(19) United States
(12) Patent Application Publication
(10) Pub. No.: US 2025/0054849 A1
(43) Pub. Date: Feb. 13, 2025

(54) CHIP PACKAGE AND METHOD FOR FORMING THE SAME

(71) Applicant: Xintec Inc., Taoyuan City (TW)

(72) Inventors: Wei-Luen SUEN, New Taipei City (TW); Po-Jung CHEN, Yunlin County (TW); Chia-Ming CHENG, New Taipei City (TW); Po-Shen LIN, New Taipei City (TW); Jiun-Yen LAI, Taipei City (TW); Tsang-Yu LIU, Zhubei City (TW); Shu-Ming CHANG, New Taipei City (TW)

(21) Appl. No.: 18/779,105

(22) Filed: Jul. 22, 2024

Related U.S. Application Data
(60) Provisional application No. 63/518,719, filed on Aug. 10, 2023.
(60) Provisional application No. 63/627,635, filed on Jan. 31, 2024.

(51) Int. Cl. H01L 23/498; H01L 21/768; H01L 23/15; H01L 23/528

(52) U.S. Cl. CPC H01L 23/49827; H01L 21/76898; H01L 23/15; H01L 23/49816; H01L 23/5283

(57) ABSTRACT

A chip package is provided. The chip package includes a device substrate, a first redistribution layer (RDL), a carrier base, and at least one conductive connection structure. The device substrate has at least one first through-via opening extending from the backside surface of the device substrate to the active surface of the device substrate. The first RDL is disposed on the backside surface of the device substrate and extends in the first through-via opening. The carrier base carries the device substrate, and has a first surface facing the backside surface of the device substrate and a second surface opposite the first surface. The conductive connection structure is disposed on the second surface of the carrier base and is electrically connected to the first RDL.

### CROSS REFERENCE TO RELATED APPLICATIONS

This application claims the benefit of U.S. Provisional Application No. 63/518,719, filed Aug. 10, 2023 and Provisional Application No. 63/627,635, filed Jan. 31, 2024, the entirety of which is incorporated by reference herein.

### BACKGROUND OF THE INVENTION

### Field of the Invention

The invention relates to a package technology, and in particular to a chip package and a method for forming the same that are capable of increasing the structure strength.

### Description of the Related Art

Optoelectronic devices have been widely used in electronic products such as desktops, laptops, tablets, mobile phones, digital cameras, digital video recorders, and the like. The chip package process is an important step in the fabrication of electronic products. Chip packages not only protect sensing chips from outside environmental contaminants, but they also provide electrical connection paths between the electronic elements inside and those outside of the chip packages.

As the application of electronic products increases, the size of the chips within the chip package may also increase. In order to mount large chips into packages, package technology faces challenges. For example, when there is a large chip in a chip scale package (CSP), the support or rigidity of the chip is often insufficient, and warping or deformation may occur, which increases the difficulty of chip packaging. However, in order to address the above problems, other problems will arise when the support or rigidity of the chip may be increased by increasing the chip's thickness. For example, increasing the difficulty of fabricating through-substrate via (TSV) electrodes within the chip.

Accordingly, there is a need for a chip package and a method for forming the same that are capable of eliminating or mitigating the aforementioned problems.

### BRIEF SUMMARY OF THE INVENTION

An embodiment of the present disclosure provides a chip package. The chip package includes a device substrate having at least one first through-via opening extending from the backside surface of the device substrate to the active surface of the device substrate. The chip package also includes a first redistribution layer, a carrier base that supports the device substrate, and at least one conductive connection structure. The first redistribution layer is disposed on the backside surface of the device substrate and extends into the first through-via opening. Furthermore, the carrier base has a first surface facing the backside surface of the device substrate and a second surface opposite the first surface. In addition, the conductive connection structure is disposed on the second surface of the carrier base and electrically connected to the first redistribution layer.

An embodiment of the present disclosure provides a method for forming a chip package. The method includes providing a device substrate that has at least one first through-via opening extending from a backside surface of the device substrate to the active surface of the device substrate. A first redistribution layer is formed on the backside surface of the device substrate and extends into the first through-via opening. The device substrate is attached to a carrier base. The carrier base has a first surface facing the backside surface of the device substrate and a second surface opposite the first surface. At least one conductive connection structure is formed on the second surface of the carrier base. The conductive connection structure is electrically connected to the first redistribution layer.

Another embodiment of the present disclosure provides a method for forming a chip package. The method includes providing a first device substrate. The device substrate has a backside surface and an active surface. The active surface is opposite the backside surface. The device substrate includes at least one through-via opening. The through-via opening extends from the backside surface to the active surface. A first redistribution layer is formed on the backside surface of the first device substrate. The first redistribution layer extends into the through-via opening. A second device substrate is bonded to the first device substrate. The second device substrate has a first surface and a second surface. The second surface is opposite the first surface. The second surface is bonded to the backside surface of the first device substrate. A molding compound material layer is formed on the backside surface of the first device substrate to fill the through-via opening and to surround the second device substrate. A second redistribution layer is formed on the molding compound material layer.

### BRIEF DESCRIPTION OF THE DRAWINGS

The present disclosure can be more fully understood by reading the subsequent detailed description and examples with references made to the accompanying drawings, wherein:

FIGS. 1A to 1E are cross-sectional views of a method for forming a chip package according to some embodiments.

FIG. 2 is a cross-sectional view of a chip package according to some embodiments.

FIGS. 3A to 3D are cross-sectional views of a method for forming a chip package according to some embodiments.

FIG. 4 is a cross-sectional view of a chip package according to some embodiments.

FIGS. 5A to 5B are cross-sectional views of a method for forming a chip package according to some embodiments.

FIG. 6 is a cross-sectional view of a chip package according to some embodiments.

FIGS. 7A to 7B are cross-sectional views illustrating a method for forming a chip package according to some embodiments.

FIG. 8 is a cross-sectional view of a chip package according to some embodiments.

FIG. 9 is a cross-sectional view of a chip package according to some embodiments.

FIG. 10 is a schematic cross-sectional view of a chip package according to some embodiments.

FIG. 11 is a cross-sectional view of a chip package according to some embodiments.

FIGS. 12A to 12G are cross-sectional views of a method for forming a chip package according to some embodiments.

FIG. 13 is a cross-sectional view of a chip package according to some embodiments.

FIGS. 14A to 14F are cross-sectional views of a method for forming a chip package according to some embodiments.

FIG. 15 is a cross-sectional view of a chip package according to some embodiments.

FIG. 16 is a cross-sectional view of a chip package according to some embodiments.

FIG. 17 is a cross-sectional view of a chip package according to some embodiments.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. In addition, the present disclosure may repeat reference numbers and/or letters in the various embodiments. This repetition is for the purpose of simplicity and clarity, and does not imply any relationship between the different embodiments and/or configurations discussed. Moreover, when a first material layer is referred to as being on or overlying a second material layer, the first material layer may be in direct contact with the second material layer, or separated from the second material layer by one or more material layers.

A chip package according to an embodiment of the present invention may be used to package micro-electro-mechanical system chips. However, embodiments of the invention are not limited thereto. For example, the chip package of the embodiments of the invention may be implemented to package active or passive devices or electronic components of integrated circuits, such as digital or analog circuits. For example, the chip package is related to optoelectronic devices, micro-electro-mechanical systems (MEMS), biometric devices, micro fluidic systems, and physical sensors measuring changes to physical quantities such as heat, light, capacitance, pressure, and so on. In particular, a wafer-level package (WSP) process may optionally be used to package semiconductor chips, such as image-sensor elements, light-emitting diodes (LEDs), solar cells, RF circuits, accelerators, gyroscopes, fingerprint recognition devices, micro actuators, surface acoustic wave devices, pressure sensors, ink printer heads, and so on.

The above-mentioned wafer-level package process mainly means that after the packaging step is accomplished during the wafer stage, the wafer with chips is diced to obtain individual packages. However, in a specific embodiment, separated semiconductor chips may be redistributed on a carrier wafer and then packaged, which may also be referred to as a wafer-level package process. In addition, the above-mentioned wafer-level package process may also be adapted to form a chip package having multi-layer integrated circuit devices by a stack of wafers having integrated circuits.

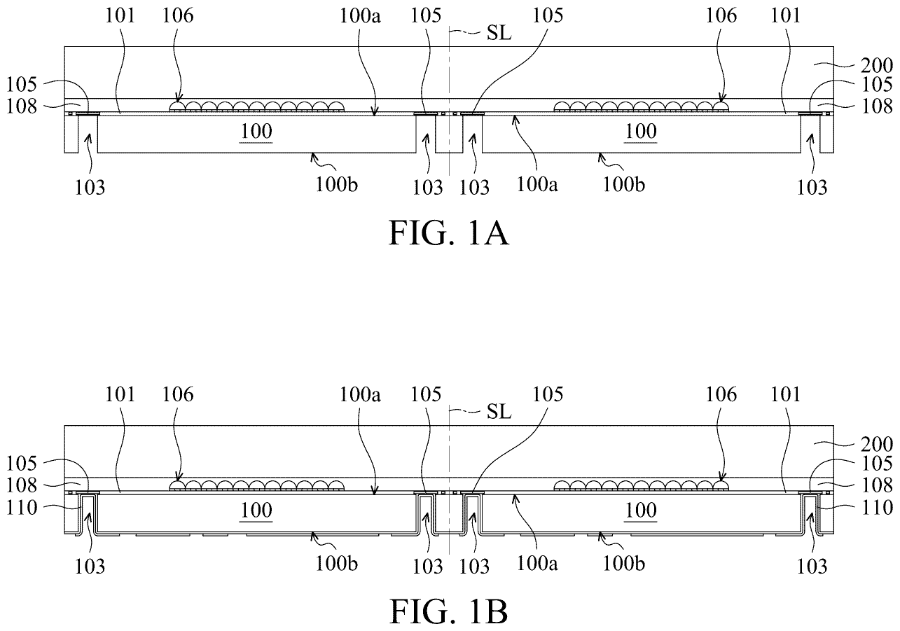

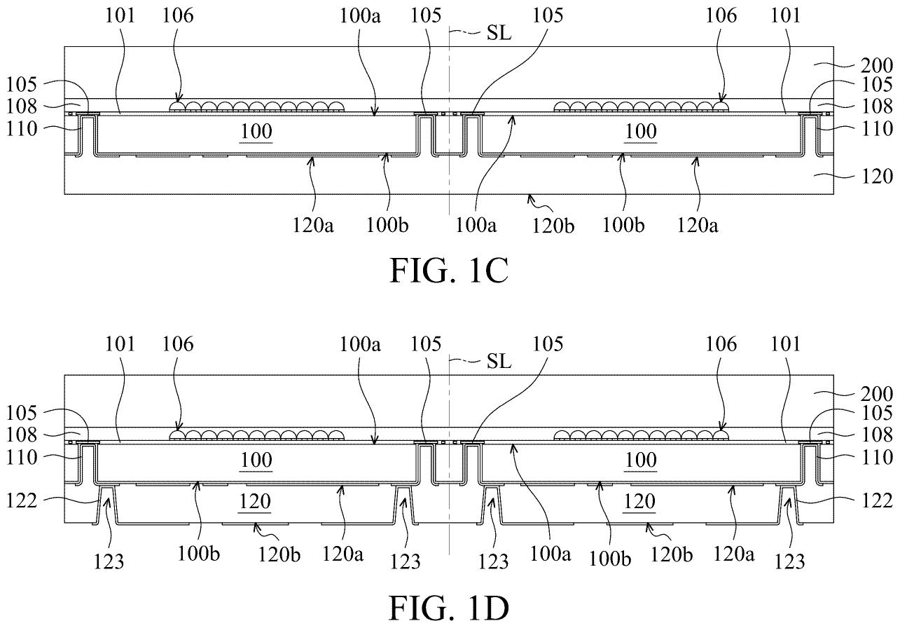

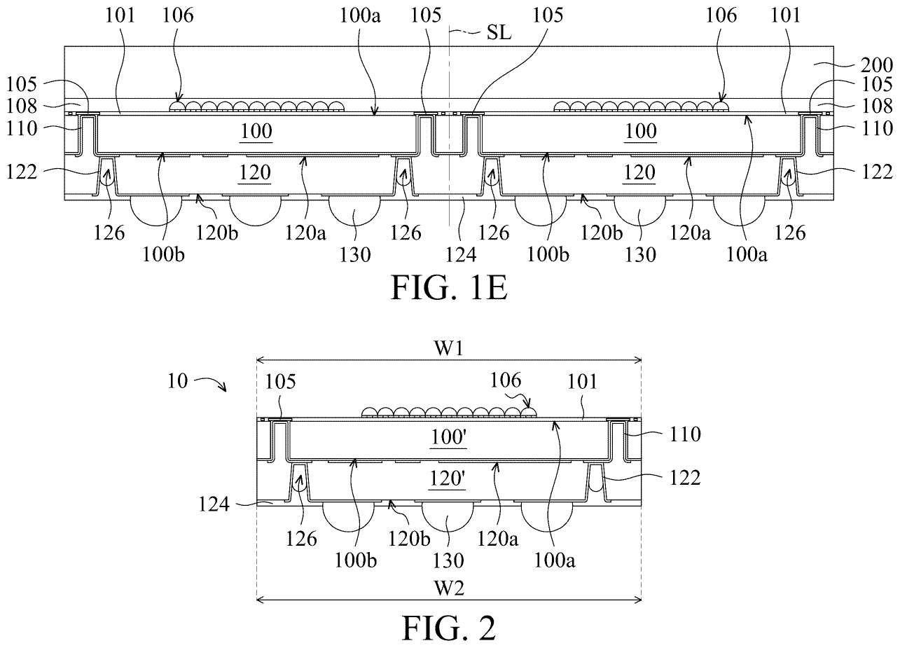

FIGS. 1A to 1E are cross-sectional views of a method for forming a circuit board 10 in a chip package in accordance with some embodiments. In some embodiments, the chip package is implemented with a front side illumination (FSI) sensing device. Referring to FIG. 1A, a device substrate 100 is provided. The device substrate 100 has an active surface 100a (for example, an upper surface or a front side surface) and an opposite backside surface 100b (for example, a lower surface or a non-active surface). The device substrate 100 has chip regions (not shown) and a scribe line region that surrounds these chip regions and separates two adjacent ones. In order to simplify the diagram, herein only two complete chip regions and a scribe line SL (indicated by a dotted line) that separates these chip regions are depicted. In some embodiments, the device substrate 100 is a silicon wafer or other suitable semiconductor wafer to facilitate wafer-level package processes. In other embodiments, the device substrate 100 may be a silicon substrate or other semiconductor substrate. In some embodiments, the device substrate 100 in the chip region includes a circuit (not shown), and signals are input and output through subsequently formed pads.

Moreover, the device substrate 100 includes an insulating layer 101 and one or more pads 105 disposed on the active surface 100a of the device substrate 100. In some embodiments, the insulating layer 101 formed on the active surface 100a may include an interlayer dielectric (ILD) layer, an inter-metal dielectric (IMD) layer, a passivation layer, or a combination thereof. In order to simplify the diagram, herein only a flat layer is depicted. Moreover, the insulating layer 101 may include inorganic materials, such as silicon oxide (e.g., SiO₂), silicon nitride, silicon oxynitride, metal oxide, or a combination thereof or another suitable insulating material. The pads 105 are formed in the insulating layer 101. In some embodiments, the pad 105 serves as an input/output (I/O) pad and may be a single layer or a multi-layer structure. In order to simplify the diagram, only the pads 105 with a single-layer structure are depicted as an example. The pads 105 may include metallic materials, such as copper, aluminum, combinations thereof, or other suitable pad materials. It is understood that the number of pads 105 depends on design requirements and is not limited to the embodiment shown in FIG. 1A.

In some embodiments, an optical component 106 is correspondingly disposed on the insulating layer 101 of each chip region. The optical component 106 corresponds to a sensing region (not shown) of the device substrate 100 in each chip region. The optical component 106 may include a microlens array, a filter layer, a combination thereof, or another suitable optical component. Moreover, the sensing region including a sensing device (not shown) is adjacent to the active surface 100a of the device substrate 100. For example, the sensing region may include an image sensing device or another suitable sensing device. In some other embodiments, the sensing region includes a device for sensing biometric identification (e.g., a fingerprint recognition device), a device for sensing environmental characteristics (e.g., a temperature sensing device t, a humidity sensing device, a pressure sensing device, a capacitive sensing device) or another suitable sensing device.

Afterwards, the active surface 100a of the device substrate 100 is attached to a carrier substrate 200 through an adhesive layer 108. The carrier substrate 200 may be made of silicon, glass, ceramic or a suitable substrate material, and may have a wafer shape to facilitate the wafer-level package process. For example, the carrier substrate 200 is a glass wafer and serves as a temporary support structure during the manufacturing of the device substrate 100. In some embodiments, the adhesive layer 108 is used as a bonding layer between the carrier substrate 200 and other structures to temporarily bond the carrier substrate 200 to other structures together. For example, the adhesive layer 108 may include temporary bonding materials, such as light-to-heat conversion (LTHC), an ultraviolet (UV) curing material, a thermal curing material or the like.

Next, a thinning process (for example, an etching process, a milling process, a grinding process or a polishing process) is performed on the backside surface 100b of the device substrate 100 to reduce the thickness of the device substrate 100. After performing the thinning process, one or more through-via openings 103 extending from the backside surface 100b to the active surface 100a of the substrate are formed in the device substrate 100. In some embodiments, through-via openings 103 are formed in the device substrate 100 in each chip region via a photolithography process and an etching process (e.g., a dry etching process, a wet etching process, a plasma etching process, a reactive ion etching process, or another suitable process). The through-via openings 103 penetrate the device substrate 100 and extend into the insulating layer 101 to expose the pads 105.

Referring to FIG. 1B, an insulating liner (not shown) is conformally formed on the backside surface 100b of the device substrate 100 by a deposition process (for example, a thermal oxidation process, a coating process, a physical vapor deposition process, a chemical vapor deposition process or another suitable process). The insulating liner is also conformally deposited on the sidewall and bottom surfaces of the through-via opening 103. In some embodiments, the insulating liner may include an inorganic material (e.g., silicon oxide, silicon nitride, silicon oxynitride, metal oxide, or a combination thereof) or another suitable insulating material. A patterned redistribution layer (RDL) 110 is formed on the insulating liner by a deposition process (e.g., a coating process, a physical vapor deposition process, a chemical vapor deposition process, an electroplating process, an electroless plating process or another suitable process), a lithography process and an etching process in sequence. For example, a conductive layer (not shown) is conformally formed on the insulating liner via an electroplating process. The conductive layer is also conformally formed on the insulating liner on the sidewall and the bottom surfaces of the through-via opening 103, and is in direct electrical contact or indirect electrical contact with the exposed pads 105 via the through-via opening 103. In some embodiments, the conductive layer may include aluminum, titanium, tungsten, copper, another suitable conductive material, or a combination thereof. Afterwards, the conductive layer is patterned sequentially through a lithography process and an etching process to form the redistribution layer 110, as shown in FIG. 1B.

In some embodiments, the redistribution layer 110 is formed on the backside surface 100b of the device substrate 100, and conformally extends to the sidewall and the bottom surfaces of the through-via openings 103. The redistribution layer 110 is electrically isolated from the device substrate 100 through the insulating liner, and is in direct electrical contact or indirect electrical contact with the exposed pads 105 via the through-via openings 103. As a result, the redistribution layer 110 in each through-via opening 103 forms a through-substrate via (TSV).

Referring to FIG. 1C, the device substrate 100 in the structure shown in FIG. 1B is placed on a carrier base 120. In some embodiments, the carrier base 120 has a first surface 120a (e.g., an upper surface) facing the backside surface 100b of the device substrate and a second surface 120b (e.g., a lower surface) opposing the first surface 120a. More specifically, the carrier base 120 covers the device substrate 100 of each chip region and partially or completely fills the through-via openings 103. The carrier base 120 is employed to carry the device substrate in the subsequently formed chip package, instead of increasing the thickness of the device substrate to enhance the structural strength or rigidity of the chip package. As a result, the thickness of the carrier base 120 is adjusted according to the size of the device substrate in the chip package, so that the chip package can have appropriate structural strength, thereby preventing the chip package from warping or deforming. In some embodiments, the carrier base 120 includes a different material (such as a molding compound material) than that of the device substrate 100.

Referring to FIG. 1D, at least one through-via opening 123 is formed in the carrier base 120. The through-via opening 123 extends from the second surface 120b to the first surface 120a. In some embodiments, one or more through-via openings 123 extending from the second surface 120b to the first surface 120a are formed in the carrier base 120. Moreover, as viewed from a top-view perspective, the through-via opening 123 is offset from the through-via opening 103 (indicated in FIG. 1A) in the device substrate 100 and exposes a portion of the redistribution layer 110 on the backside surface 100b of the device substrate 100 in each chip region. In some embodiments, the through-via opening 123 is formed through a photolithography process and an etching process (e.g., a dry etching process, a wet etching process, a plasma etching process, a reactive ion etching process, or another suitable process).

Thereafter, a patterned redistribution layer 122 is formed on the carrier base 120 by a deposition process (for example, coating process, physical vapor deposition process, chemical vapor deposition process, electroplating process, electroless plating process or another suitable process), a lithography process and an etching process are performed in sequence. For example, a conductive layer (not shown) is conformally formed on the carrier base 120 via an electroplating process. The conductive layer is also conformally formed on the sidewall surface and the bottom surface of the through-via opening 123 and is in direct electrical contact or indirect electrical contact with the exposed redistribution layer 110 via the through-via opening 123. The conductive layer may include aluminum, titanium, tungsten, copper or a combination thereof or another suitable conductive material. Afterwards, the conductive layer is patterned via a photolithography process and an etching process in sequence, to form the redistribution layer 122 that is in electrical contact with the redistribution layer 110. Similarly, the redistribution layer 122 within each through-via opening 123 forms a through-mold via (TMV). In this embodiment, the device substrate 100 and the carrier base 120 have through-via openings 103 and through-via openings 123, respectively, which are offset from each other (as viewed from a top-view perspective). Therefore, compared with a chip package without using a carrier base and with increasing the thickness of the device substrate, it is possible to avoid manufacturing high aspect ratio TSVs in the device substrate, thereby reducing the difficulty of manufacturing package.

Referring to FIG. 1E, an insulating layer 124 and at least one conductive connection structure 130 are formed on the second surface 120b of the carrier base 120 in sequence. In some embodiments, the insulating layer 124 is formed to cover the redistribution layer 122 and partially fills the through-via opening 123, and a hole 126 that is covered by the insulating layer 122 is formed in the through-via opening 123. More specifically, the insulating layer 124 (also called a passivation layer) is formed on the second surface 120b of the carrier base 120 via a deposition process, and fills the through-via opening 103 to cover the redistribution layer 122 including the through-mold vias. In some embodiments, the insulating layer 124 only partially fills each through-via opening 123, so that the holes 126 are covered by the insulating layer 124 and formed between the redistribution layer 122 and the insulating layer 124 in the through-via opening 123. The holes 126 can serve as buffers between the insulating layer 124 and the redistribution layer 122 to reduce undesired stress as a result of mismatch of thermal expansion coefficients. In some embodiments, the interface between the hole 126 and insulating layer 124 has an arcuate contour. In other some embodiments, the insulating layer 124 can also completely fill the through-via opening 103. The insulating layer 124 may include an epoxy resin, a solder mask, an organic polymer material (such as polyimide, butylcyclobutene (BCB), parylene, polynaphthalenes, fluorocarbons, or acrylates), or another suitable insulating material.

Afterwards, one or more conductive connection structures 130 (e.g., solder balls, bumps or conductive pillars) are formed on the second surface 120b of the carrier base 120. In some embodiments, the conductive connection structure 130 passes through the insulating layer 124 and is electrically connected to the exposed redistribution layer 122. In one embodiment, the conductive connection structure 130 includes tin, lead, copper, gold, nickel, or a combination thereof.

After attaching the device substrate 100 to the carrier base 120 and forming the conductive connection structure 130, the carrier substrate 200 is de-bonded, and the carrier base 120 and the device substrate 100 are diced along the scribe line SL to form a single chip package 10, as shown in FIG. 2. In some embodiments, when the adhesive layer 108 is made of a light-to-heat conversion (LTHC) material, a de-bonding process is performed by irradiating the adhesive layer 108 with laser light or ultraviolet light. Due to the heat generated by laser light or ultraviolet light, the light-to-heat conversion (LTHC) material will decompose, so that the carrier substrate 200 is removed from the structure including the carrier base 120 and the device substrate 100.

Referring to FIG. 2 again, the chip package 10 includes a singulated device substrate 100′ stacked on the diced carrier base 120′. In some embodiments, the device substrate 100′ has one or more through-via openings (e.g., through-via openings 103, indicated in FIG. 1A) that extend from the backside surface 100b to active surface 100a. The carrier base 120′ has one or more through-via openings (e.g., through-via openings 123, indicated in FIG. 1D) that extend from the second surface 120b to the first surface 120a, where the first surface 120a faces the backside surface 100b of the device substrate 100′. Moreover, a portion of the carrier base 120′ extends into the through-via opening 103.

In some embodiments, the carrier base 120′ includes a molding compound material and has a lateral dimension W2 that is substantially equal to the lateral dimension W1 of the device substrate 100′, so that the edges of the carrier base 120′ are substantially vertically aligned with the edges of the device substrate 100′.

In some embodiments, the chip package 10 further includes redistribution layers 110 and 122. The redistribution layer 110 is disposed on the backside surface 100b of the device substrate 100′ and extends into the through-via opening 103, while the redistribution layer 122 is disposed on the second surface 120b of the carrier base 120′ and extends into the through-via opening 123. Moreover, the through-via opening 123 exposes a portion of the redistribution layer 110, so that the redistribution layer 122 is in electrical contact with the redistribution layer 110.

In some embodiments, the chip package 10 further includes an insulating layer 124 and a conductive connection structure 130, which are disposed on the second surface 120b of the carrier base 120′. The insulating layer 124 covers the redistribution layer 122 and partially fills the through-via opening 123 to form a hole 126 covered by the insulating layer 124. The conductive connection structure 130 passes through the insulating layer 124 and is electrically connected to the redistribution layer 110 via the redistribution layer 122.

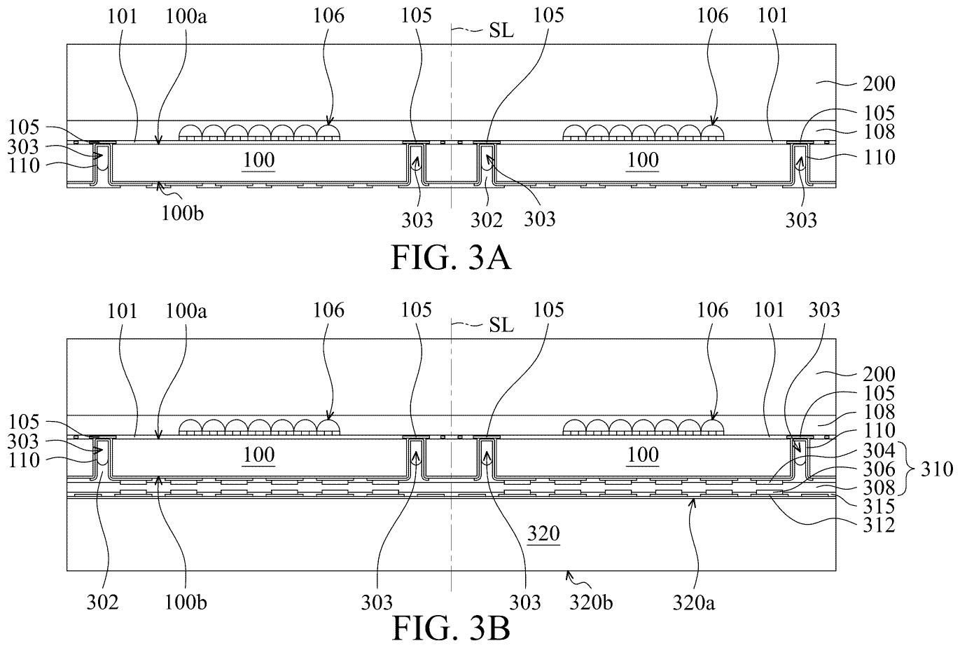

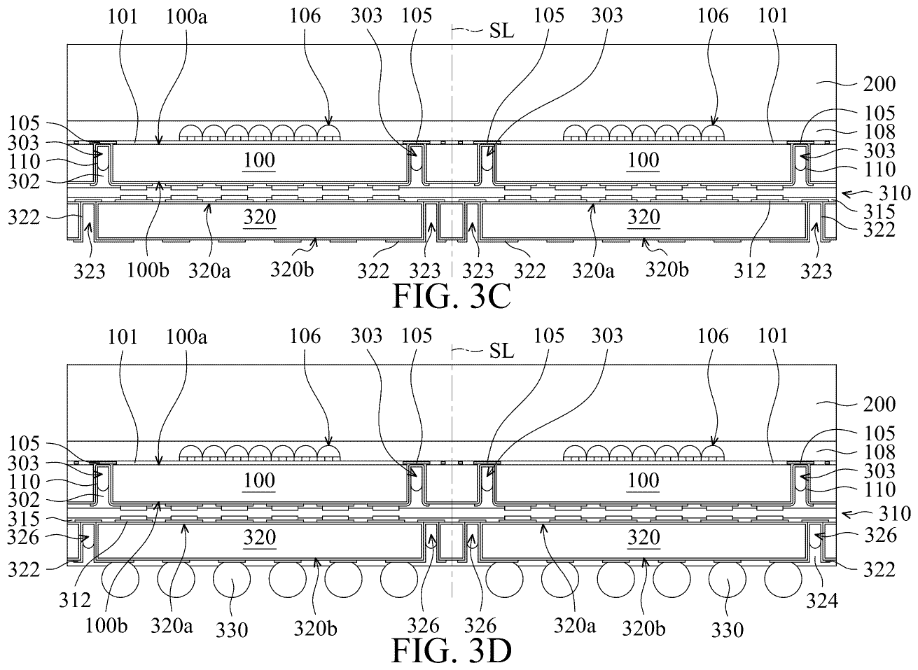

FIGS. 3A to 3D are cross-sectional views of a method for forming a chip package 20 according to some embodiments. Elements in FIGS. 3A to 3D that are the same as those in FIGS. 1A to 1E are labeled with the same reference numbers as in FIGS. 1A to 1E and are not described again for brevity. Referring to FIG. 3A, in some embodiments, the structure shown in FIG. 1B is provided, and an insulating layer 302 is formed to cover the redistribution layer 110 and partially fills the through-via opening (for example, the through-via opening 103, as shown in FIG. 1A), so as to form a hole 303 covered by the insulating layer 302 in the through-via opening 103. The materials and formation methods used for the insulating layer 302 may be the same or similar to the materials and formation methods used for the insulating layer 302 in the chip package 10 (as shown in FIG. 2).

Afterwards, referring to FIG. 3B, in some embodiments, an interconnection structure 310 is provided, and the device substrate 100 is attached to a carrier base 320 via the interconnection structure 310. In some embodiments, the interconnection structure 310 may include one or more first conductive bumps 304, one or more corresponding second conductive bumps 308, and an anisotropic conductive film (ACF) 306. The first conductive bumps 304 and the second conductive bumps 308 are respectively formed on two opposite sides of the anisotropic conductive film (ACF) 306. In some embodiments, the first conductive bumps 304 may be formed on the redistribution layer 110 first, and the second conductive bumps 308 may be formed on the corresponding pads 312 of the carrier base 320 first. Next, the device substrate 100 is attached to the carrier base 320 via the ACF 306. As a result, the ACF 306 is electrically connected between the first conductive bump 304 and the second conductive bump 308. In some embodiments, the first conductive bump 304 and the second conductive bump 308 may include solder balls or conductive pillars.

In this embodiment, the carrier base 320 has a similar structure to the device substrate 100 of each chip region. However, unlike the device substrate 100, the carrier base 320 does not have any circuit devices or sensing regions. In some embodiments, the carrier base 320 has a first surface 320a (e.g., an upper surface) and an opposite second surface 320b (e.g., a lower surface). In some embodiments, the carrier base 320 is a silicon wafer or another suitable semiconductor wafer to facilitate the wafer-level package process. Moreover, the carrier base 320 includes an insulating layer 315 and one or more pads 312 disposed on the first surface 320a of the carrier base 320. In some embodiments, the material and structure of the insulating layer 315 may be the same as or similar to those of the insulating layer 101. The pad 312 is formed in the insulating layer 315, and its material and structure may be the same or similar to those of the pad 105.

Next, Referring to FIG. 3C, in some embodiments, a thinning process is performed on the second surface 320b of the carrier base 320, so that the carrier base 320 reaches a desired thickness. The thickness of the carrier base 320 is adjusted according to the size of the device substrate in the chip package to avoid warping or deformation of the chip package. After the thinning process, one or more through-via openings 323 extending from the second surface 320b to the first surface 320a are formed in the carrier base 320, to expose the pads 312 in the insulating layer 315. The formation of the through-via openings 323 may be the same as or similar to the formation of the through-via opening 103. Afterwards, an insulating liner (not shown) is conformally formed on the second surface 320b of the carrier base 320 and on the sidewall and the bottom surfaces of the through-via opening 323. Next, a patterned redistribution layer 322 is formed on the insulating liner. The material and formation method of the redistribution layer 322 may be the same as or similar to those of the redistribution layer 110. The redistribution layer 322 is electrically isolated from the carrier base 320 through the insulating liner, and is directly or indirectly electrically connected to the exposed pads 312 via the through-via openings 323. As a result, the redistribution layer 322 in each through-via opening 323 forms a through-substrate via (TSV). In this embodiment, the device substrate 100 and the carrier base 320 have the through-via opening 103 and the through-via opening 323, respectively. Therefore, it is possible to avoid manufacturing high aspect ratio TSVs in the device substrate, thereby reducing the difficulty of manufacturing package.

Referring to the FIG. 3D, in some embodiments, an insulating layer 324 and at least one conductive connection structure 330 are formed on the second surface 320b of the carrier base 320 in sequence. In some embodiments, the insulating layer 324 covers the redistribution layer 322 and partially fills the through-via opening 323, so as to form a hole 326 covered by the insulating layer 324 in the through-via opening 323. Moreover, the materials and formation methods used for the insulating layer 324 may be the same as or similar to those of the insulating layer 124 (as shown in FIG. 1E). In some embodiments, the conductive connection structure 330 passes through the insulating layer 324 and is electrically connected to the exposed redistribution layer 322. Moreover, the materials and formation methods used for the conductive connection structure 330 may be the same or similar to those of the conductive connection structure 130 (as shown in FIG. 1E).

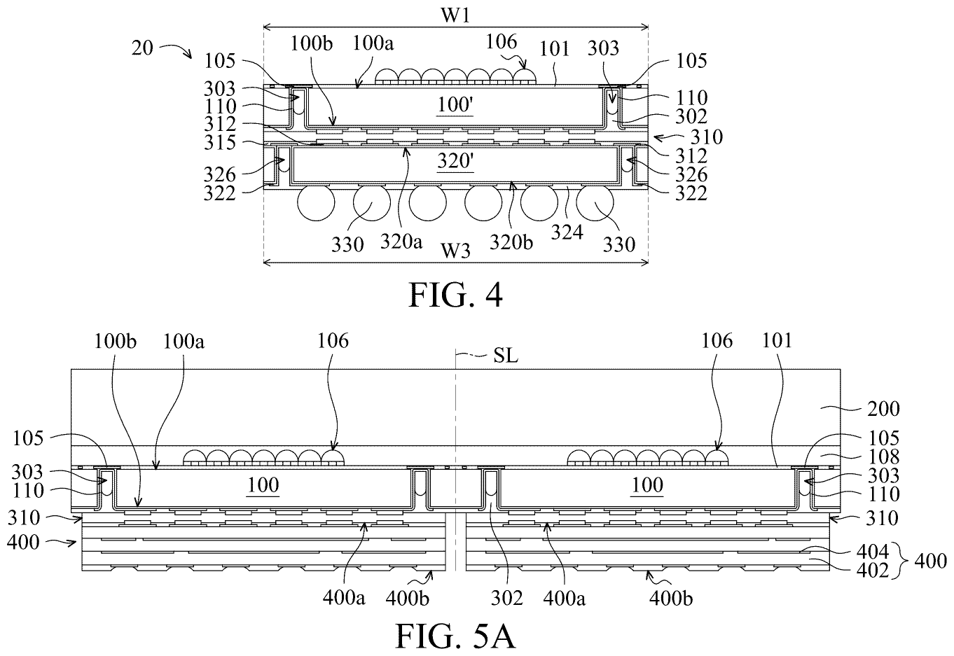

Afterwards, the carrier substrate 200 is de-bonded and the carrier base 320, the interconnection structure 310 and the device substrate 100 are diced along the scribe line SL to form a singulated chip package 20, as shown in FIG. 4.

Referring to FIG. 4 again, the chip package 20 includes a singulated device substrate 100′, a diced carrier base 320′, and an interconnection structure 310 disposed between the device substrate 100′ and the carrier base 320′. In some embodiments, the device substrate 100 has one or more through-via openings that extend from the backside surface 100b to the active surface 100a. The carrier base 320′ has one or more through-via openings that extend from the second surface 320b to the first surface 320a, where the first surface 320a is attached to the backside surface 100b of the device substrate 100′ via the interconnection structure 310.

In some embodiments, the carrier base 320′ includes a semiconductor substrate (e.g., a silicon substrate) and has a lateral dimension W3 that is substantially equal to a lateral dimension W1 of the device substrate 100′ and a lateral dimension of the interconnection structure 310, so that the edges of the carrier base 320′ are substantially vertically aligned with the edges of the device substrate 100′ and the edges of the interconnection structure 310.

In some embodiments, the chip package 20 further includes redistribution layers 110 and 322. The redistribution layer 110 is disposed on the backside surface 100b of the device substrate 100′ and extends into the through-via opening of the device substrate 100′, while the redistribution layer 122 is disposed on the second surface 320b of the carrier base 320′ and extends into the through-via opening 123 of the carrier base 320′. Moreover, the redistribution layer 122 is in electrical contact with the redistribution layer 110 via the pads 312 and the interconnection structure 3110 in sequence.

In some embodiments, the chip package 20 further includes an insulating layer 324 and a conductive connection structure 330, which are disposed on the second surface 320b of the carrier base 320′. The insulating layer 324 covers the redistribution layer 322 and partially fills the through-via opening of the carrier base 320′ to form a hole 326 covered by the insulating layer 324. The conductive connection structure 330 passes through the insulating layer 324 and is electrically connected to the redistribution layer 110 via the redistribution layer 322.

FIGS. 5A to 5B are cross-sectional views of a method for forming a chip package 30 according to some embodiments. Elements in FIGS. 5A to 5B that are the same as those in FIGS. 1A to 1E or 3A to 3D are labeled with the same reference numbers as in FIGS. 1A to 1E or 3A to 3D and are not described again for brevity. Referring to FIG. 5A, in some embodiments, a structure as shown in FIG. 3A is provided. Afterwards, in some embodiments, interconnection structure 310 and a carrier base 400 are provided for each chip region of the device substrate 100, and each carrier base 400 is attached to one of chip regions of the device substrate 100 via the interconnection structure 310. In this embodiment, the interconnection structure 310 and the carrier base 400 do not extend below the scribe line SL (i.e., the edge of the chip region).

In some embodiments, the first conductive bumps 304 of each interconnection structure 310 is first formed on the redistribution layer 110 of the corresponding chip region, and the second conductive bumps 308 is first formed on the corresponding carrier base 400. Afterwards, these carrier bases 400 are attached to the device substrate 100 via the ACF 306 of the interconnection structure 310.

In this embodiment, the carrier base 400 has a first surface 400a (e.g., an upper surface) and an opposite second surface 400b (e.g., a lower surface). In some embodiments, the carrier base 400 is a circuit board and includes an insulating substrate 402 and a multi-layer metallization structure 404 disposed in the insulating substrate 402. The metal layers within the multi-layer metallization structure 404 are electrically connected via vertical conductive features (not shown). In some embodiments, the uppermost metal layer in the multi-layer metallization structure 404 has pad patterns (not shown) that correspond to and are in contact with the second conductive bumps 308 of the interconnection structure 310.

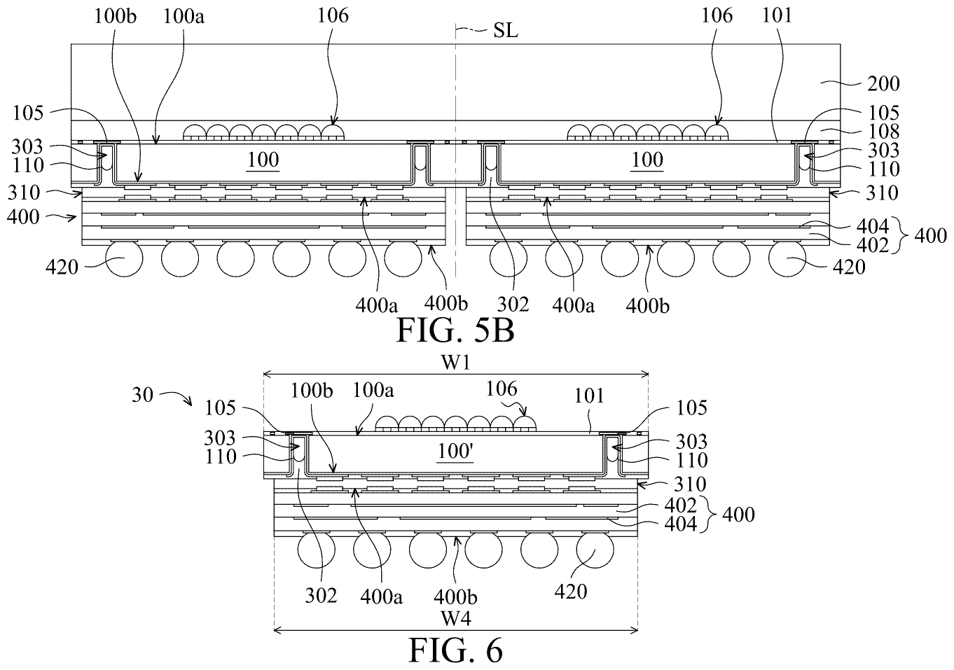

Next, referring to FIG. 5B, at least one conductive connection structure 420 is formed on the second surface 400b of the carrier base 400, so that the lowermost metal layer in the multi-layer metallization structure 404 has pad patterns (not shown) corresponding to and in electrical contact with the conductive connection structures 420. The materials and formation methods used for the conductive connection structures 420 are the same as or similar to those of the conductive connection structure 330 (as shown in FIG. 3D). In this embodiment, since the carrier base 400 has the multi-layer metallization structure 404 therein, it is beneficial to increase the flexibility of routing design in the circuit and/or increase the number of pads corresponding to the conductive connection structures 420. Afterwards, the carrier substrate 200 is de-bonded and the device substrate 100 is diced along the scribe line SL to form a singulated chip package 30, as shown in FIG. 6.

Referring to FIG. 6 again, the chip package 30 includes a singulated device substrate 100′, a carrier base 400 (for example, a circuit board), and an interconnection structure 310 disposed between the device substrate 100′ and the carrier base 400. In some embodiments, the device substrate 100 has one or more through-via openings 103 that extend from the backside surface 100b to the active surface 100a. The carrier base 400 does not have a through-via opening, and the first surface 400a is attached to the backside surface 100b of the device substrate 100′ via the interconnection structure 310. In some embodiments, the carrier base 400 has a lateral dimension W4 that is substantially equal to the lateral dimension of the interconnection structure 310 and smaller than the lateral dimension W1 of the device substrate 100′, so that the edges of the carrier base 400 are substantially vertically aligned with the edges of the interconnection structure 310, but are not aligned with the edges of the device substrate 100′.

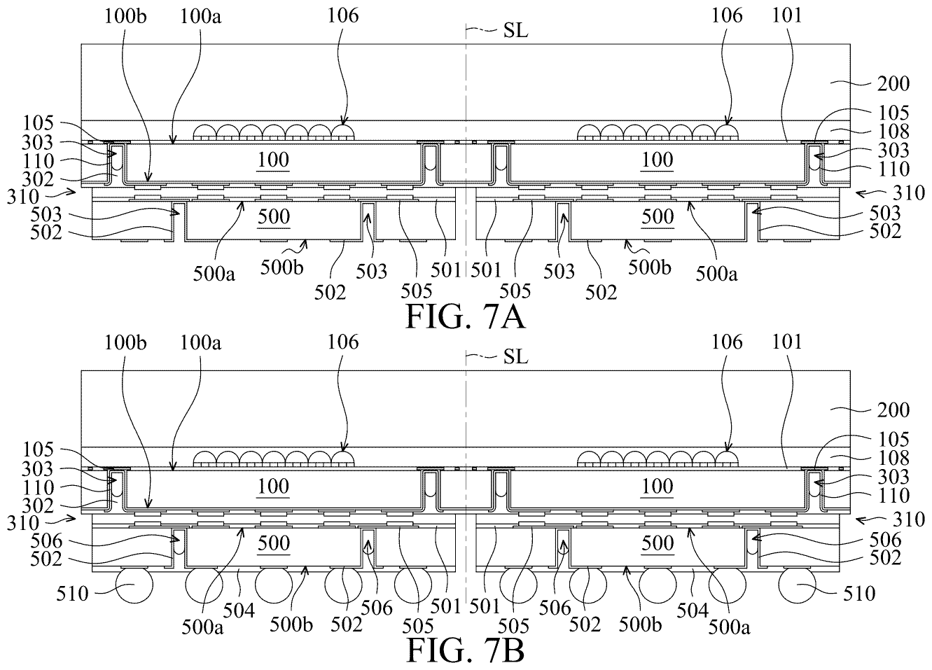

FIGS. 7A to 7B are cross-sectional views of the method for the chip package 40 according to some embodiments. Elements in FIGS. 7A to 7B that are the same as those in FIGS. 1A to 1E, 3A to 3D or 5A to 5B are labeled with the same reference numbers as in FIGS. 1A to 1E, 3A to 3D or 5A to 5B and are not described again for brevity. Referring to FIG. 7A, in some embodiments, a structure as shown in FIG. 3A is provided. Afterwards, in some embodiments, an interconnection structure 310 and a carrier base 500 are provided for each chip region of the device substrate 100, and each carrier base 500 is attached to one of the chip regions of the device substrate 100 via the interconnection structure 310. In this embodiment, the interconnection structure 310 and the carrier base 500 do not extend below the scribe line SL (i.e., the edge of the chip region).

In some embodiments, the first conductive bumps 304 of each interconnection structure 310 is first formed on the redistribution layer 110 of the corresponding chip region, and the second conductive bumps 308 is first formed on the corresponding carrier base 500. Next, these carrier bases 500 are attached to the device substrate 100 via the ACF 306 of the interconnection structure 310.

In this embodiment, the carrier base 500 has a first surface 500a (e.g., an upper surface) and an opposite second surface 500b (e.g., a lower surface). In this embodiment, the carrier base 500 has a similar structure to the device substrate 100 of each chip region. However, unlike the device substrate 100, the carrier base 500 does not have any circuit devices or sensing regions. More specifically, the carrier base 500 is a glass substrate. Moreover, the carrier base 500 includes an insulating layer 501 and one or more pads 505 formed on the first surface 500a of the carrier base 500. In some embodiments, the material and structure of the insulating layer 515 may be the same as or similar to those of the insulating layer 101. The pads 505 are formed in the insulating layer 515, and their material and structure may be the same as or similar to those of the pads 105. In some embodiments, the thickness of the carrier base 500 is adjusted according to the size of the device substrate in the chip package to avoid warping or deformation of the chip package. The carrier base 500 has one or more through-via openings 503 extending from the second surface 500b to the first surface 500a to expose the pads 505 in the insulating layer 501. The formation of the through-via openings 503 may be the same as or similar to those of the through-via openings in the device substrate 100. There is a redistribution layer 502 on the second surface 500b of the carrier base 500 and in the through-via openings 503. The material and formation method of the redistribution layer 502 may be the same as or similar to those of the redistribution layer 110. The redistribution layer 502 is directly or indirectly electrically connected to the exposed pads 505 via the through-via openings 503. As a result, the redistribution layer 502 in each through-via opening 503 forms a through-substrate via (TSV). In this embodiment, the device substrate 100 and the carrier base 500 respectively have through-via openings. Therefore, it is possible to avoid manufacturing high aspect ratio TSVs in the device substrate, thereby reducing the difficulty of manufacturing package.

Next, referring to FIG. 7B, in some embodiments, an insulating layer 504 and at least one conductive connection structure 510 are formed on the second surface 500b of the carrier base 500 in sequence. In some embodiments, the insulating layer 504 covers the redistribution layer 502 and partially fills the through-via openings 503 (indicated in FIG. 7A), and forms a hole 506 covered by the insulating layer 504 in the through-via opening 503. Moreover, the materials and formation methods used for the insulating layer 504 may be the same as or similar to those of the insulating layer 302 In some embodiments, the conductive connection structures 510 pass through the insulating layer 504 and are electrically connected to the exposed redistribution layer 502. Moreover, the materials and formation methods used for the conductive connection structures 510 may be the same as or similar to the conductive connection structures 330 (as shown in FIG. 3D). Afterwards, the carrier substrate 200 is de-bonded and the device substrate 100 is diced along the scribe line SL to form a singulated chip package 40, as shown in FIG. 8.

Referring to FIG. 8 again, the chip package 40 includes a singulated device substrate 100′, a carrier base 500′ (for example, a glass substrate), and an interconnection structure disposed between the device substrate 100′ and the carrier base 500′. In some embodiments, the device substrate 100′ has through-via openings extending from the backside surface 100b to the active surface 100a. The carrier base 500 has through-via openings extending from the second surface 500b to the first surface 500a, where the first surface 500a is attached to the backside surface 100b of the device substrate 100′ via the interconnection structure 310. In some embodiments, the carrier base 500 has a lateral dimension W5 that is substantially equal to the lateral dimension of the interconnection structure 310 and smaller than the lateral dimension W1 of the device substrate 100′, so that the edges of the carrier base 500 are substantially vertically aligned with the edges of the interconnection structure 310, but are not aligned with the edges of the device substrate 100′.

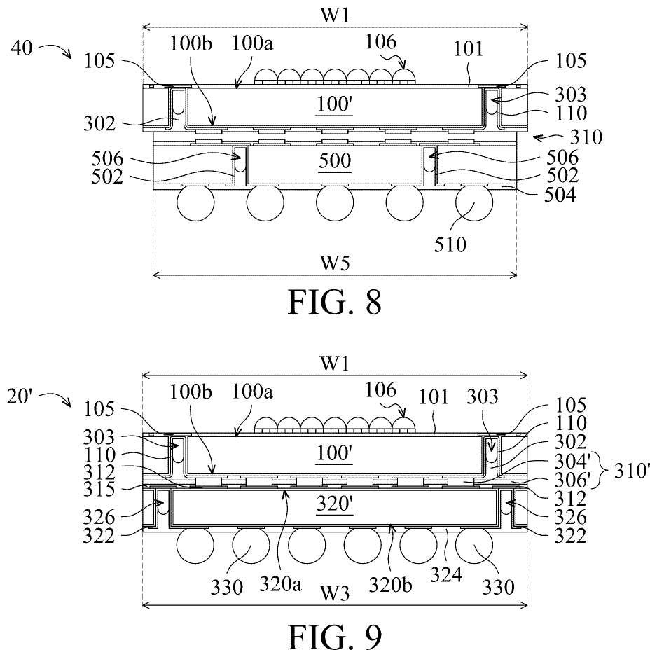

Referring to FIG. 9, which is a cross-sectional view of a chip package 20′ according to some embodiments. Elements in FIG. 9 that are the same as those in FIG. 4 are labeled with the same reference numbers as in FIG. 4 and are not described again for brevity. In some embodiments, the structure of the chip package 20′ is similar to the chip package 20 of FIG. 4. Unlike the interconnection structure 310 of the chip package 20, the interconnection structure 310′ includes one or more conductive bumps 304′ and an adhesive layer 306′. The conductive bumps 304′ are disposed in the adhesive layer 306′. The device substrate 100′ is attached to the carrier base 320 via the adhesive layer 306′. Moreover, the conductive bump 304′ is electrically connected between the redistribution layer 110 and the conductive connection structure 330.

In some embodiments, the formation method of the chip package 20′ is similar to the chip package 20 of FIG. 4. The difference is that the conductive bumps 304′ is first formed on the redistribution layer 110 and then bonded to the corresponding pads 312 of the carrier base 320. Afterwards, the device substrate 100 is attached to the carrier base 320 via the adhesive layer 306′. In some embodiments, the conductive bumps 304 may include solder balls or conductive pillars. Moreover, the adhesive layer 306′ may include an underfill material, a molding compound material, or a combination thereof.

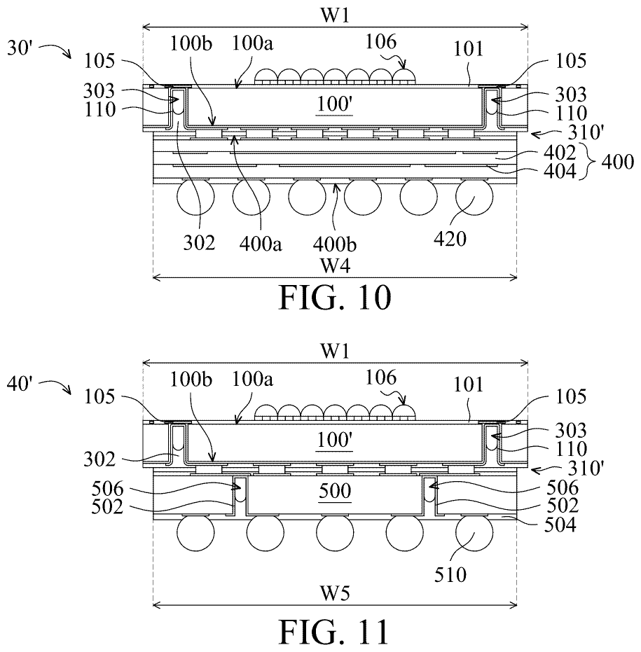

Referring to FIG. 10, which is a cross-sectional view of a chip package 30′ according to some embodiments. Elements in FIG. 10 that are the same as those in FIGS. 6 and 9 are labeled with the same reference numbers as in FIGS. 6 and 9 and are not described again for brevity. In some embodiments, the structure of the chip package 30′ is similar to the chip package 30 of FIG. 6. Unlike the interconnection structure 310 of the chip package 30, the interconnection structure 310′ includes one or more conductive bumps 304′ and an adhesive layer 306′. The conductive bumps 304′ are disposed in the adhesive layer 306′. The device substrate 100′ is attached to the carrier base 400 via the adhesive layer 306′. Moreover, the conductive bump 304′ is electrically connected between the redistribution layer 110 and the conductive connection structure 420.

In some embodiments, the formation method of the chip package 30′ is similar to the chip package 30 of FIG. 6. The difference is that the conductive bumps 304′ is first formed on the redistribution layer 110 and then bonded to the corresponding pads of the carrier base 400 (e.g., the pad patterns of the uppermost metal layer in the multi-layer metallization structure 404). Afterwards, the device substrate 100 is attached to the carrier base 400 via the adhesive layer 306′.

Referring to FIG. 11, which illustrates a schematic cross-sectional view of a chip package 40′ according to some embodiments. Elements in FIG. 11 that are the same as those in FIGS. 8 and 9 are labeled with the same reference numbers as in FIGS. 8 and 9 and are not described again for brevity. In some embodiments, the structure of the chip package 40′ is similar to the chip package 40 of FIG. 8. Unlike the interconnection structure 310 of the chip package 40, the interconnection structure 310′ may include one or more conductive bumps 304′ and an adhesive layer 306′. The conductive bumps 304′ are disposed in the adhesive layer 306′. The device substrate 100′ is attached to the carrier base 500 through the adhesive layer 306′. Moreover, the conductive bump 304′ is electrically connected between the redistribution layer 110 and the conductive connection structure 510.

In some embodiments, the formation method of the chip package 40′ is similar to the chip package 40 of FIG. 8. The difference is that the conductive bumps 304′ is first formed on the redistribution layer 110 and then bonded to the corresponding pads 505 of the carrier base 500. Afterwards, the device substrate 100′ is attached to the carrier base 500 through the adhesive layer 306′.

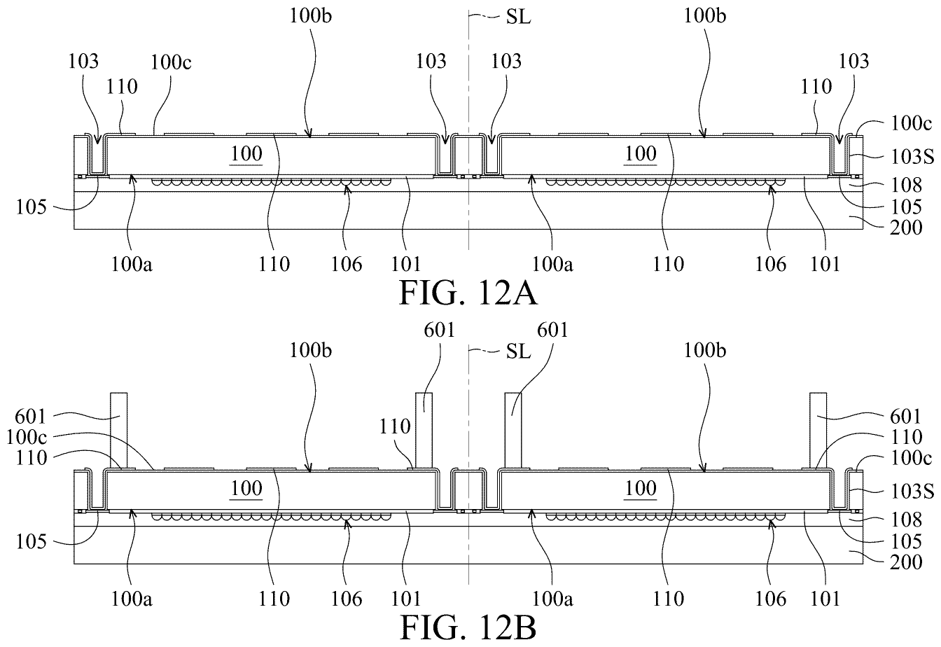

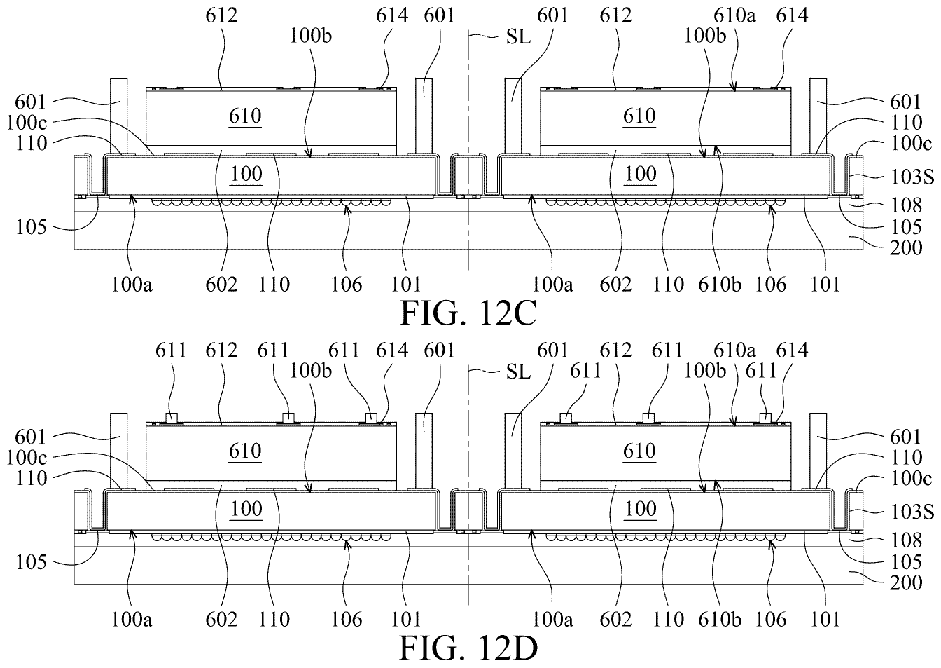

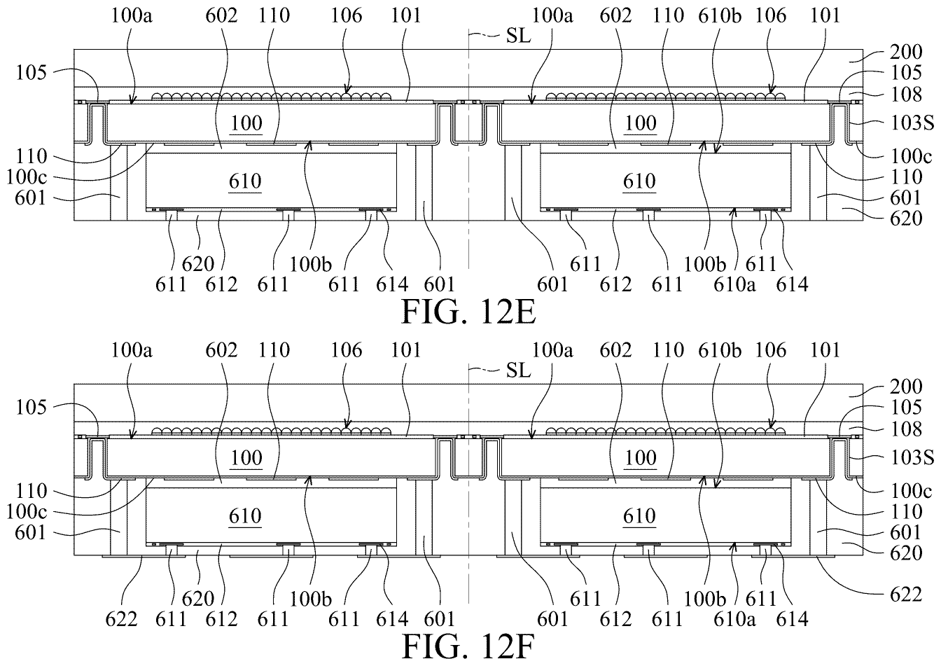

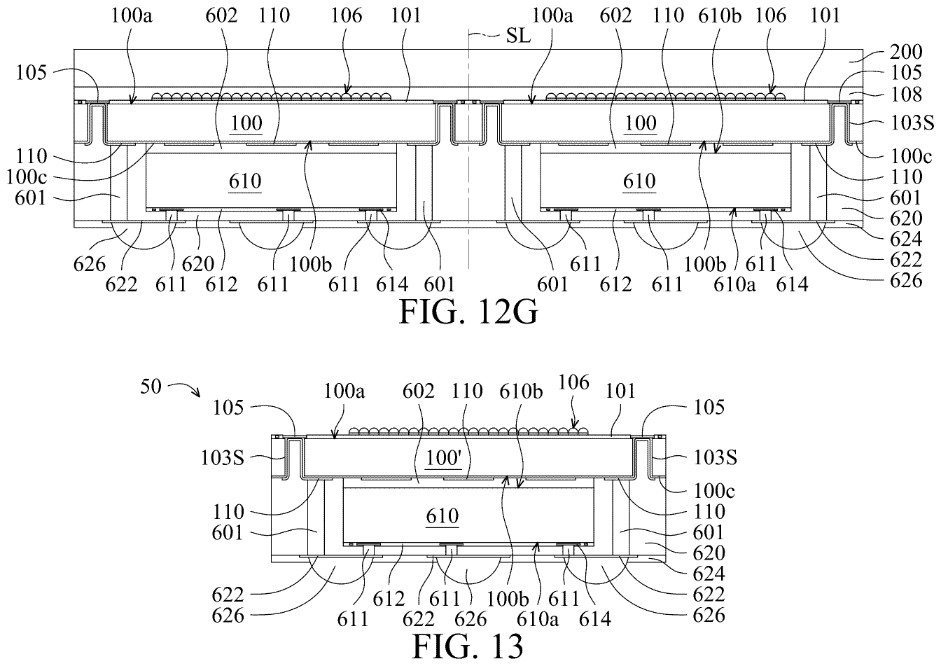

FIGS. 12A to 12G are cross-sectional views of a method for forming a chip package 50 according to some embodiments. Elements in FIGS. 12A to 12G that are the same as those in FIGS. 1A to 1E are labeled with the same reference numbers as in FIGS. 1A to 1E and are not described again for brevity. Referring to FIG. 12A, in some embodiments, a structure that is similar to the structure shown in FIG. 1B is provided. Unlike the structure shown in FIG. 1B, the structure specifically depicts the insulating liner 100c (not shown in FIG. 1B) that is conformally formed on the backside surface 100b of the device substrate 100 and the sidewall and bottom surfaces of the through-via opening 103.

Referring to FIG. 12B, there are one or more conductive pillars 601 on and electrically connected to the redistribution layer 110 near the through-via openings 103 in each chip region in accordance with some embodiments. The conductive pillars 601 may be formed by a deposition process. For example, the deposition process may be an electroplating process. The conductive pillars 601 may include copper, aluminum, titanium, tungsten, copper, another suitable conductive material, or a combination thereof.

Referring to FIG. 12C, a device substrate 610 is bonded to the device substrate 100 in each chip region in accordance with some embodiments. More specifically, the device substrate 610 has an active surface 610a and a backside surface 610b opposite the active surface 610a. In some embodiments, the backside surface 610b of the device substrate 610 is bonded to the backside surface 100b of the device substrate 100 via an adhesive layer 602. For example, the adhesive layer 602 may be a die attach film. In some embodiments, the lateral dimension of the device substrate 100 is greater than the lateral dimension of the device substrate 610. Furthermore, similar to the device substrate 100, the device substrate 610 includes an insulating layer 612 and one or more pads 614 disposed on the active surface 610a of the device substrate 610. In some embodiments, the insulating layer 101 includes an interlayer dielectric (ILD) layer, an inter-metal dielectric (IMD) layer, a passivation layer, or a combination thereof. Furthermore, the pads 614 are formed in the insulating layer 612 and have a top surface exposed from the insulating layer 612 to serve as an input/output (I/O) pad.

Referring to FIG. 12D, one or more conductive pillars 611 are formed on the exposed pads 614 to be electrically connected to the device substrate 610 in accordance with some embodiments. The conductive pillars 611 may be formed by a deposition process. For example, the deposition process is an electroplating process. The conductive pillars 611 may include copper, aluminum, titanium, tungsten, copper, another suitable conductive material, or a combination thereof.

Referring to FIG. 12E, in some embodiments, a molding compound material layer 620 is formed on the backside surface 100b of the device substrate 100 in each chip region to fill the through-via openings 103 and also cover and surround the device substrate 610 and the conductive pillars 601 and 611 in each chip region. The upper surface of the molding compound material layer 620 faces the backside surface 100b of the device substrate 100 and covers the device substrate 100 of each chip region and partially or completely fills the through-via openings 103.

Afterwards, in some embodiments, the excess molding compound material layer 620 is removed from the lower surface of the molding compound material layer 620 by a polishing process, such as a chemical mechanical polishing process, so as to expose the conductive pillars 601 and 611. The molding compound material layer 620 may serve as a carrier base to carry the device substrates 100 and 610 in the subsequently formed chip package, instead of increasing the thickness of the device substrate 100 to enhance the structural strength or rigidity of the chip package.

Referring to FIG. 12F, a redistribution layer 622 is formed on the lower surface of the compound material layer 620 in accordance with some embodiments. The material and formation method of the patterned redistribution layer 622 may be the same as or similar to those of the redistribution layer 122 shown in FIG. 1D. The redistribution layer 622 is used to electrically connect the conductive pillars 601 to the conductive pillars 611

Referring to FIG. 12G, an insulating layer 624 and one or more conductive connection structures 626 are formed on the lower surface of the molding compound material layer 620 in sequence in accordance with some embodiments. In some embodiments, the insulating layer 624 is formed to cover the redistribution layer 622. The material and the formation method of the insulating layer 624 may be the same as or similar to those of the insulating layer 124 shown in FIG. 1E.

Afterwards, one or more conductive connection structures 626 (e.g., solder balls, bumps or conductive pillars) are formed over the lower surface of the molding compound material layer 620. In some embodiments, the conductive connection structure 626 passes through the insulating layer 624, so as to be electrically connected to the redistribution layer 622. The material and the formation method of the conductive connection structures 626 may be the same as or similar to those of the conductive connection structures 130 shown in FIG. 1E.

Afterwards, the carrier substrate 200 is de-bonded, and the molding compound material layer 620 and the device substrate 100 are diced along the scribe line SL to form a single chip package 50, as shown in FIG. 13.

Referring to FIG. 13 again, the chip package 50 includes a singulated device substrate 100′ stacked on the molding compound material layer 620 and the device substrate 610 in the molding compound material layer 620 and stacked below the device substrate 100′. In some embodiments, the device substrate 100′ has one or more through-via openings (e.g., through-via openings 103, indicated in FIG. 12A) that are filled with the molding compound material layer 620. The conductive pillars 601 extend between the redistribution layer 110 to the redistribution layer 622, and the conductive pillars 611 extend between the device substrate 610 and the redistribution layer 622.

In some embodiments, the lateral dimension of the diced molding compound material layer 620 is substantially equal to the lateral dimension of the device substrate 100′, so that the edges of the diced molding compound material layer 620 are substantially vertically aligned with the edges of the device substrate 100′.

In some embodiments, the chip package 50 further includes an insulating layer 624 and conductive connection structures 626 which are disposed on the lower surface of the molding compound material layer 620. The conductive connection structures 626 pass through the insulating layer 624 and are electrically connected to the redistribution layer 110 via the redistribution layer 622.

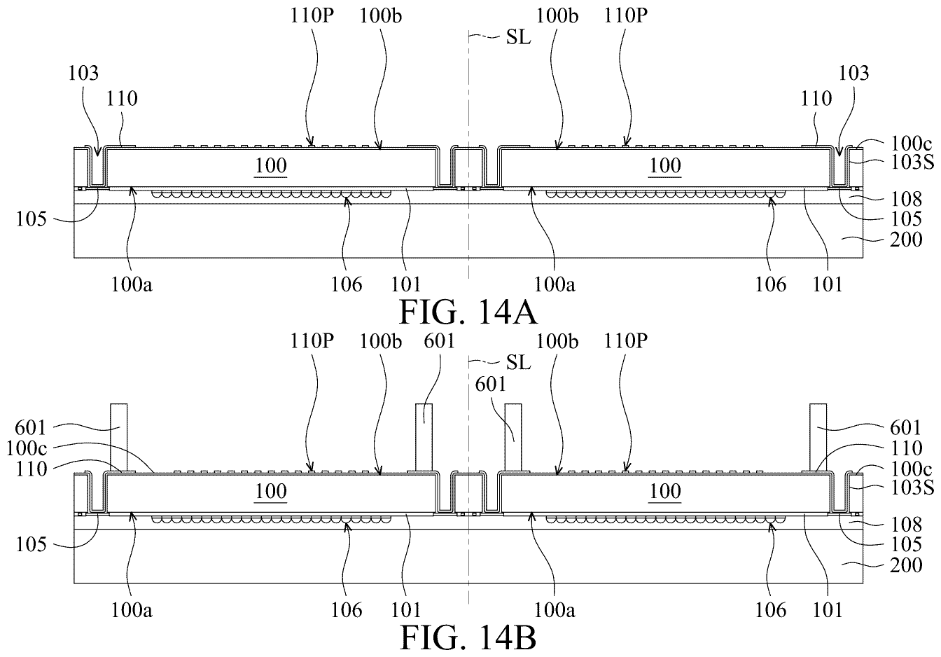

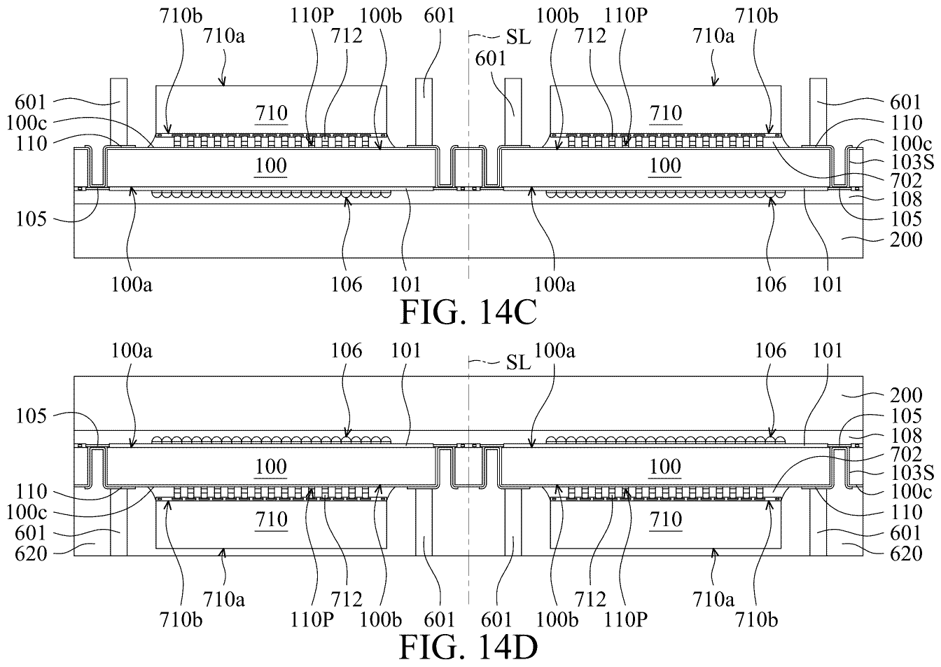

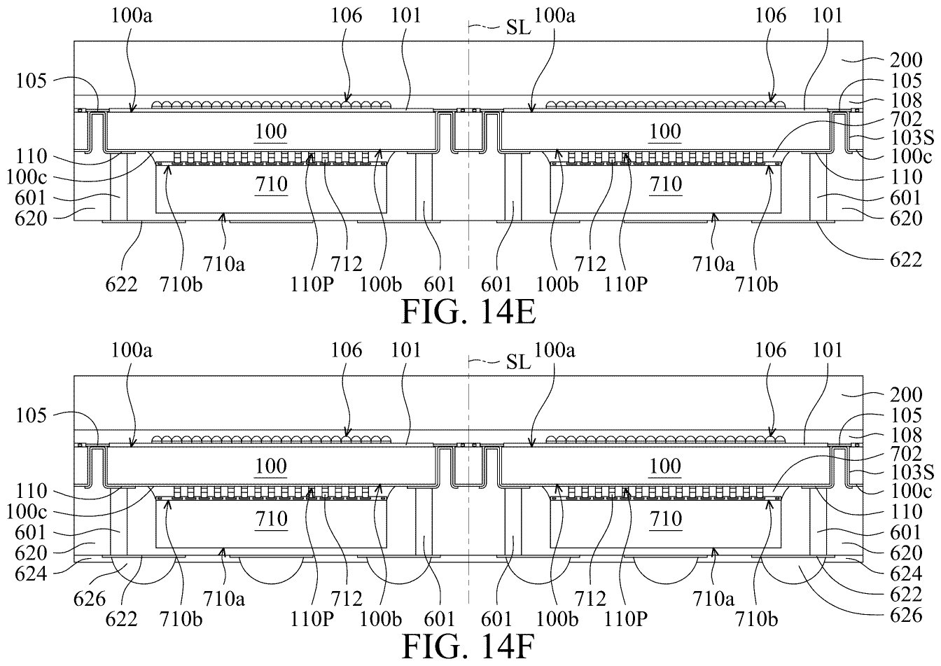

FIGS. 14A to 14F are cross-sectional views of a method for forming a chip package 50 according to some embodiments. Elements in FIGS. 14A to 14F that are the same as those in FIGS. 1A to 1E or FIGS. 12A to 12G are labeled with the same reference numbers as in FIGS. 1A to 1E or FIGS. 12A to 12G and are not described again for brevity. Referring to FIG. 14A, in some embodiments, a structure that is similar to the structure shown in FIG. 12A is provided. Unlike the structure shown in FIG. 12A, the redistribution layer 110 shown in FIG. 14A further includes pad patterns 110P that are arranged over a region of the backside surface 100b of the device substrate 100 in each chip region used for subsequently stacking another device substrate.

Referring to FIG. 14B, there are one or more conductive pillars 601 on and electrically connected to the redistribution layer 110 near the through-via openings 103 in each chip region in accordance with some embodiments. Afterwards, referring to FIG. 14C, a device substrate 710 is bonded to the device substrate 100 in each chip region in accordance with some embodiments. More specifically, the device substrate 710 has a backside surface 710a and an active surface 710b opposite the backside surface 710a. In some embodiments, one or more conductive connection structures 712 that are formed on the active surface 710b of the device substrate 710 are electrically connected to the pad patterns 110P that are formed on the backside surface 100b of the device substrate 100 in each chip region. Furthermore, an adhesive layer 702 is formed between the active surface 710b of the device substrate 710 and the corresponding backside surface 100b of the device substrate 100, so as to bond the device substrate 710 to the device substrate 100 in each chip region. For example, the adhesive layer 702 may be an underfill material layer.

Referring to FIG. 14D, in some embodiments, a molding compound material layer 620 is formed on the backside surface 100b of the device substrate 100 in each chip region to fill the through-via openings 103 and also to cover and surround the device substrate 710 and the conductive pillars 601 in each chip region. The upper surface of the molding compound material layer 620 faces the backside surface 100b of the device substrate 100 and covers the device substrate 100 of each chip region and partially or completely fills the through-via openings 103.

Afterwards, in some embodiments, the excess molding compound material layer 620 is removed from the lower surface of the molding compound material layer 620 by a polishing process, such as a chemical mechanical polishing process, so as to expose the conductive pillars 601. As shown in FIG. 14D, in some embodiments, the backside surface 710a of the device substrate 710 is still covered by the molding compound material layer 620 after the polishing process when the top of the conductive pillars 601 is higher than the backside surface 710a of the device substrate 710.

Referring to FIG. 14E, a redistribution layer 622 is formed on the lower surface of the compound material layer 620 in accordance with some embodiments. The redistribution layer 622 is electrically connected to the conductive pillars 601. Referring to FIG. 14F, an insulating layer 624 and one or more conductive connection structures 626 are formed on the lower surface of the molding compound material layer 620 in sequence in accordance with some embodiments. In some embodiments, the insulating layer 624 is formed to cover the redistribution layer 622.

Afterwards, one or more conductive connection structures 626 (e.g., solder balls, bumps or conductive pillars) are formed over the lower surface of the molding compound material layer 620. In some embodiments, the conductive connection structure 626 passes through the insulating layer 624, so as to be electrically connected to the redistribution layer 622.

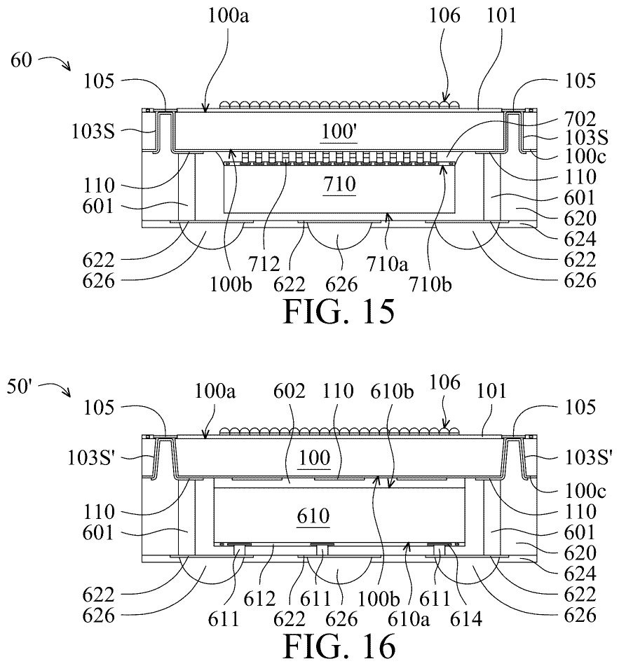

Afterwards, the carrier substrate 200 is de-bonded, and the molding compound material layer 620 and the device substrate 100 are diced along the scribe line SL to form a single chip package 60, as shown in FIG. 15.

Referring to FIG. 15 again, the chip package 60 includes a singulated device substrate 100′ stacked on the molding compound material layer 620 and the device substrate 710 in the molding compound material layer 620 and stacked below the device substrate 100′. In some embodiments, the device substrate 100′ has one or more through-via openings (e.g., through-via openings 103, indicated in FIG. 14A) that are filled with the molding compound material layer 620. The conductive pillars 601 extend between the redistribution layer 110 to the redistribution layer 622, and the conductive pillars 611 extend between the device substrate 610 and redistribution layer 622.

In some embodiments, the lateral dimension of the diced molding compound material layer 620 is substantially equal to the lateral dimension of the device substrate 100′, so that the edges of the diced molding compound material layer 620 are substantially vertically aligned with the edges of the device substrate 100′.

In some embodiments, the chip package 60 further includes an insulating layer 624 and conductive connection structures 626 which are disposed on the lower surface of the molding compound material layer 620. The conductive connection structures 626 pass through the insulating layer 624 and are electrically connected to the redistribution layer 110 via the redistribution layer 622.

Refer to FIG. 16, which illustrates a schematic cross-sectional view of a chip package 50′ according to some embodiments. Elements in FIG. 50′ that are the same as those in FIG. 13 are labeled with the same reference numbers as in FIG. 13 and are not described again for brevity. In some embodiments, the structure of the chip package 50′ is similar to the chip package 50 of FIG. 13. As shown in FIG. 13, the through-via openings 103 have vertical sidewalls 103S that extend from the backside surface 100b of the device substrate 100′ to the active surface 100a of the device substrate 100′ in accordance with some embodiments. Unlike the vertical sidewalls 103S of the through-via openings 103 in the chip package 50, the through-via openings 103 in the chip package 50′ have tapered sidewalls 103S′ that extend from the backside surface 100b of the device substrate 100′ to the active surface 100a of the device substrate 100′ in accordance with some embodiments. The tapered sidewalls 103S′ increase the process window and the reliability of the formation of the redistribution layer 110. In some embodiments, the formation method of the chip package 50′ is similar to that of the chip package 50 of FIG. 13.

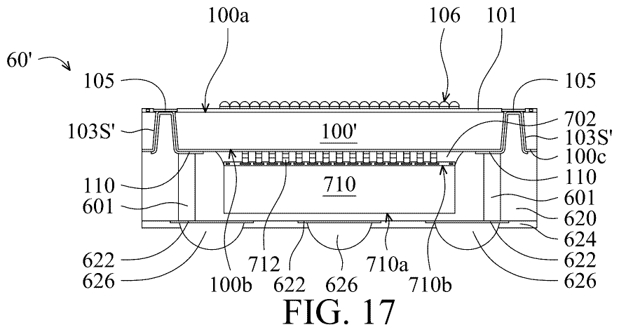

Refer to FIG. 17, which illustrates a schematic cross-sectional view of a chip package 60′ according to some embodiments. Elements in FIG. 60′ that are the same as those in FIG. 15 or 16 are labeled with the same reference numbers as in FIG. 15 or 16 and are not described again for brevity. In some embodiments, the structure of the chip package 60′ is similar to the chip package 60 of FIG. 15. As shown in FIG. 15, the through-via openings 103 have vertical sidewalls 103S that extend from the backside surface 100b of the device substrate 100′ to the active surface 100a of the device substrate 100′ in accordance with some embodiments. Unlike the vertical sidewalls 103S of the through-via openings 103 in the chip package 60, the through-via openings 103 in the chip package 60′ have tapered sidewalls 103S′ that are the same as those in chip package 50′ as shown in FIG. 16, so as to increase the process window and the reliability of the formation of the redistribution layer 110. In some embodiments, the formation method of the chip package 60′ is similar to that of chip package 60 of FIG. 15.

According to the above embodiments, without increasing the thickness of the device substrate, the structural strength or rigidity of the chip package can be improved by attaching a carrier base with the underside of the device substrate in the chip package. As a result, the thickness of the carrier base is adjusted according to the size of the device substrate in the chip package, so that the chip package can have appropriate structural strength, thereby preventing the chip package from warping or deforming. According to the above embodiments, through-via openings are formed in the device substrate and the carrier base, respectively. As a result, it is possible to avoid manufacturing high aspect ratio TSVs in the device substrate, thereby reducing the difficulty of manufacturing package. According to the above embodiments, the circuit board is used as the carrier base attached to the device substrate. As a result, the multi-layer metallization structure in the circuit board can be used for increasing the flexibility of the routing design in the circuit and/or increase the number of pads corresponding to the conductive connection structures.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A chip package, comprising:
a first device substrate having at least one first through-via opening extending from a backside surface of the device substrate to an active surface of the device substrate;
a first redistribution layer disposed on the backside surface of the device substrate and extending into the first through-via opening;
a carrier base that supports the first device substrate and has a first surface facing the backside surface of the first device substrate and a second surface opposite the first surface; and
at least one conductive connection structure disposed on the second surface of the carrier base and electrically connected to the first redistribution layer.

2. The chip package as claimed in claim 1, wherein the carrier base has at least one second through-via opening extending from the second surface of the carrier base to the first surface of the carrier base.

3. The chip package as claimed in claim 2, further comprising:
a second redistribution layer disposed on the second surface of the carrier base and extending into the second through-via opening; and
an insulating layer covering the second redistribution layer and partially filling the second through-via opening to form a hole covered by the insulating layer in the second through-via opening.

4. The chip package as claimed in claim 3, wherein the second through-via opening exposes a portion of the first redistribution layer on the backside surface of the device substrate, so that the second redistribution layer is in electrical contact with the first redistribution layer.

5. The chip package as claimed in claim 1, wherein the carrier base includes a molding compound material and has a lateral dimension that is substantially equal to a lateral dimension of the device substrate, and wherein the molding compound material fills the first through-via opening.

6. The chip package as claimed in claim 1, further comprising:
an insulating layer covering the first redistribution layer and partially filling the first through-via opening to form a hole covered by the insulating layer in the first through-via opening; and
an interconnection structure disposed between the insulating layer and the carrier base, and electrically connected between the first redistribution layer and the conductive connection structure.

7. The chip package as claimed in claim 6, wherein the interconnection structure comprises:
an anisotropic conductive film; and
a first conductive bump and a second conductive bump disposed on two opposite sides of the anisotropic conductive film, respectively, wherein the first conductive bump is electrically connected between the anisotropic conductive film and the first redistribution layer, and the second conductive bump is electrically connected between the anisotropic conductive film and the conductive connection structure.

8. The chip package as claimed in claim 6, further comprising:
an adhesive layer that attaches the device substrate to the carrier base; and
at least one conductive bump disposed in the adhesive layer, wherein the conductive bump is electrically connected between the first redistribution layer and the conductive connection structure.

9. The chip package as claimed in claim 8, wherein the adhesive layer includes am underfill material, a molding compound material, or a combination thereof.

10. The chip package as claimed in claim 6, wherein the carrier base includes a glass substrate and has a lateral dimension that is smaller than the lateral dimension of the device substrate and substantially equal to a lateral dimension of the interconnection structure.

11. The chip package as claimed in claim 6, wherein the carrier base includes a semiconductor substrate having a lateral dimension that is substantially equal to the lateral dimension of the device substrate and a lateral dimension of the interconnection structure.

12. The chip package as claimed in claim 6, wherein the carrier base comprises:
an insulating substrate having a lateral dimension that is smaller than the lateral dimension of the device substrate and substantially equal to the lateral dimension of the interconnection structure; and
a multi-layer metallization structure disposed in the insulating base and electrically connected between the interconnection structure and the conductive connection structure.

13. The chip package as claimed in claim 1, further comprising:
a second device substrate disposed in the carrier base and bonded to the backside surface of the first device substrate, having a first surface and a second surface opposite the first surface of the second device substrate; and
a second redistribution layer disposed on the second surface of the carrier base.

14. The chip package as claimed in claim 13, further comprising:
at least one first conductive pillar disposed in the carrier base to electrically connect the first redistribution layer to the second redistribution layer; and
at least one second conductive pillar disposed in the carrier base to electrically connect the second device substrate to the second redistribution layer.

15. The chip package as claimed in claim 13, further comprising:
an adhesive layer bonding the second surface of the second device substrate to the backside surface of the first device substrate.

16. The chip package as claimed in claim 15, wherein the adhesive layer is a die attach film and the first surface is an active surface of the second device substrate.

17. The chip package as claimed in claim 15, wherein the adhesive layer is an underfill material layer and the second surface is an active surface of the second device substrate.

18. The chip package as claimed in claim 17, further comprising:
at least one second conductive connection structure in the underfill material layer, wherein the second conductive connection structure is electrically connected between the second device substrate and the first device substrate.

19. The chip package as claimed in claim 13, wherein the first device substrate has a lateral dimension that is greater than a lateral dimension of the second device substrate.

20. The chip package as claimed in claim 1, wherein the first through-via opening has vertical or tapered sidewalls extending from the backside surface of the first device substrate to the active surface of the first device substrate.

21. A method for forming a chip package, comprising:
providing a device substrate, having at least one first through-via opening extending from a backside surface of the device substrate to an active surface of the device substrate;
forming a first redistribution layer on the backside surface of the device substrate and extending into the first through-via opening;
attaching the device substrate to a carrier base, wherein the carrier base has a first surface facing the backside surface of the device substrate and a second surface opposite the first surface; and
forming at least one conductive connection structure formed on the second surface of the carrier base, wherein the conductive connection structure is electrically connected to the first redistribution layer.

22. A method for forming a chip package, comprising:
providing a first device substrate, having a backside surface and an active surface opposite the backside surface and including at least one through-via opening extending from the backside surface to the active surface;
forming a first redistribution layer on the backside surface of the first device substrate and extending into the through-via opening;
bonding a second device substrate to the first device substrate, wherein the second device substrate has a first surface and a second surface opposite the first surface and bonded to the backside surface of the first device substrate;
forming a molding compound material layer on the backside surface of the first device substrate to fill the through-via opening and to surround the second device substrate; and
forming a second redistribution layer on the molding compound material layer.
